(19) United States
(12) Patent Application Publication
(10) Pub. No.: US 2019/0245162 A1
(43) Pub. Date: Aug. 8, 2019

(54) QUANTUM DOT FILM AND APPLICATIONS THEREOF

(71) Applicant: SABIC GLOBAL TECHNOLOGIES B.V., Bergen op Zoom (NL)

(72) Inventors: Chunim LEE, Gyeonggi-do (KR); Sunyoung LEE, Gyeonggi-do (KR); Seongnam LEE, Seoul-Si (KR); Jong Woo LEE, Gyeonggi-do (KR); Soonyoung HYUN, Gyeonggi-do (KR)

(21) Appl. No.: 16/336,802

(22) PCT Filed: Sep. 28, 2017
(86) PCT No.: PCT/IB2017/055978

§ 371 Date: Mar. 26, 2019

Related U.S. Application Data
(60) Provisional application No. 62/400,838, filed on Sep. 28, 2016.

(51) Int. Cl. H01L 51/52; H01L 51/50; H01L 51/56

(52) U.S. Cl. CPC H01L 51/5253; H01L 51/56; H01L 51/502

(57) ABSTRACT

A film for light emitting devices is disclosed. In an aspect, the film is formed from a process comprising: disposing a quantum dot solution on a barrier layer; curing the quantum dot solution to form a quantum dot layer adhered to the barrier layer; disposing a protective solution on the quantum dot layer; and curing the protective solution to form a protective layer adhered to the quantum dot layer, wherein the film comprises a stack of the barrier layer, the quantum dot layer, and the protective layer, and wherein the protective layer inhibits the permeation of at least oxygen and moisture into the quantum dot layer.

### TECHNICAL FIELD

The disclosure generally relates to light emitting device and methods and more particularly to methods and structures utilizing a quantum dot film.

### BACKGROUND

Direct conversion of electricity into light using semiconductor-based light-emitting diodes (LEDs) is widely accepted one of the most promising approaches to more efficient lighting. LEDs demonstrate high brightness, long operational lifetime, and low energy consumption performance that far surpass that of conventional lighting systems such as incandescent and fluorescent light sources. The LED field is currently dominated by semiconductor quantum-well emitters (based, e.g., on indium gallium nitride (InGaN)/gallium nitride (GaN)) fabricated by epitaxial methods on crystalline substrates (e.g., sapphire). These structures are highly efficient, reliable, mature and bright, but structural defects at the substrate and semiconductor interface caused by lattice mismatch and heating during operation generally limits such devices to point light source with limited flexible compatibility.

Organic light emitting diodes (OLEDs) are easily amendable to low-temperature, large-area processing, including fabrication on flexible substrates. Synthetic organic chemistry provides essentially an unlimited number of degrees of freedom for tailoring molecular properties to achieve specific functionality, from selective charge transport to color-tunable light emission. The prospect of high-quality lighting sources based on inexpensive “plastic” materials has driven a tremendous amount of research in the area of OLEDs, which in turn has led to the realization of several OLED-based high-tech products such as flat screen televisions and mobile communication devices. Several industrial giants such as Samsung, LG, Sony, and Panasonic are working to develop large-area white-emitting OLEDs both for lighting and display. Despite advances in the OLED field, there are a few drawbacks of this technology that might prevent its widespread use in commercial products. One problem is poor cost-efficiency caused at least in part by the complexity of the necessary device architecture, which requires multiple thermal deposition steps during manufacture. Another problem is their limited stability, particularly for deep-red and blue phosphorescent OLEDs. While improving greatly in recent years, they still do not meet the standards employed in high-end devices.

Chemically synthesized nanocrystal quantum dots (QDs) have emerged as a promising class of emissive materials for low-cost yet efficient LEDs. These luminescent nanomaterials feature size-controlled tunable emission wavelengths and provide improvements in color purity, stability and durability over organic molecules. In addition, as with organic materials, colloidal QDs may be fabricated and processed via inexpensive solution-based techniques compatible with lightweight, flexible substrates. Moreover, similar to other semiconductor materials, colloidal QDs feature almost continuous above-band-edge absorption and a narrow emission spectrum at near-band-edge energies. Distinct from bulk semiconductors, however, the optical spectra of QDs depend directly on their size. Specifically, their emission color may be continuously tuned from the infrared (IR) to ultraviolet (UV) by varying QD size and/or composition. The wide range spectral tunability is combined with high photoluminescence (PL) quantum yields (QYs) that approach unity in well-passivated structures. These unique properties of QDs have been explored for use in various devices such as LEDs, lasers, solar cells, and photo detectors.

It is known that the quantum dots may degrade when they are exposed in air and moisture (e.g., water). In presence of light, oxygen and moisture molecules may cause photo-oxidation and photo-corrosion on the surface of the quantum dots. Once quantum dots react with oxygen and moisture, new defects may be created on the surface of quantum dots. Such defects may result in decreased light emitting of quantum dots.

In conventional quantum dot films, a quantum dot layer 101 may be disposed between a first barrier film 103 and a second barrier film 105, as illustrated in FIG. 1. Suitable barrier films include polymers (e.g., polyethylene terephthalate (PET)), oxides such as silicon oxides, metal oxides, metal nitrides, metal carbides, metal oxynitrides, and combinations thereof. The barrier layers are typically formed using techniques employed in the film metallizing art such as sputtering, evaporation, chemical vapor deposition, plasma deposition, atomic layer deposition, plating and the like. Second barrier film is typically laminated on a quantum dot layer and often includes an adhesion surface or layer. The thickness of each of the conventional barrier layer is configured to eliminate wrinkling in a roll-to-roll or laminate manufacturing processes, as may be required by conventional methods described above.

Improvements in quantum dot films and methods of making the same, are needed.

### SUMMARY

A film for light emitting devices is disclosed. In an aspect, the film is formed from a process comprising: disposing a quantum dot solution on a barrier layer; curing the quantum dot solution to form a quantum dot layer adhered to the barrier layer; disposing a protective solution on the quantum dot layer; and curing the protective solution to form a protective layer adhered to the quantum dot layer, wherein the film comprises a stack of the barrier layer, the quantum dot layer, and the protective layer, and wherein the protective layer inhibits the permeation of at least oxygen and moisture into the quantum dot layer.

In another aspect, an article comprises: a barrier layer comprising a substrate interposed between a diffuser layer and an inorganic layer; a quantum dot layer disposed on the barrier layer; a protective layer disposed on the quantum dot layer, the protective layer comprising a functional layer disposed adjacent one or more of an inorganic layer and a hybrid layer, wherein the protective layer inhibits the permeation of at least oxygen and moisture into the quantum dot layer.

In yet another aspect, a method comprises: disposing a quantum dot solution on a barrier layer; curing the quantum dot solution to form a quantum dot layer adhered to the barrier layer; disposing a protective solution on the quantum dot layer; and curing the protective solution to form a protective layer adhered to the quantum dot layer, wherein the film comprises a stack of the barrier layer, the quantum dot layer, and the protective layer, and wherein the protective layer inhibits the permeation of at least oxygen and moisture into the quantum dot layer.

### BRIEF DESCRIPTION OF THE DRAWINGS

The above-mentioned and other features and advantages of this disclosure, and the manner of attaining them, will become apparent and be better understood by reference to the following description of one aspect of the disclosure in conjunction with the accompanying drawings, wherein:

FIG. 1 is a schematic representation of a composite layered structure according to aspects of the prior art.

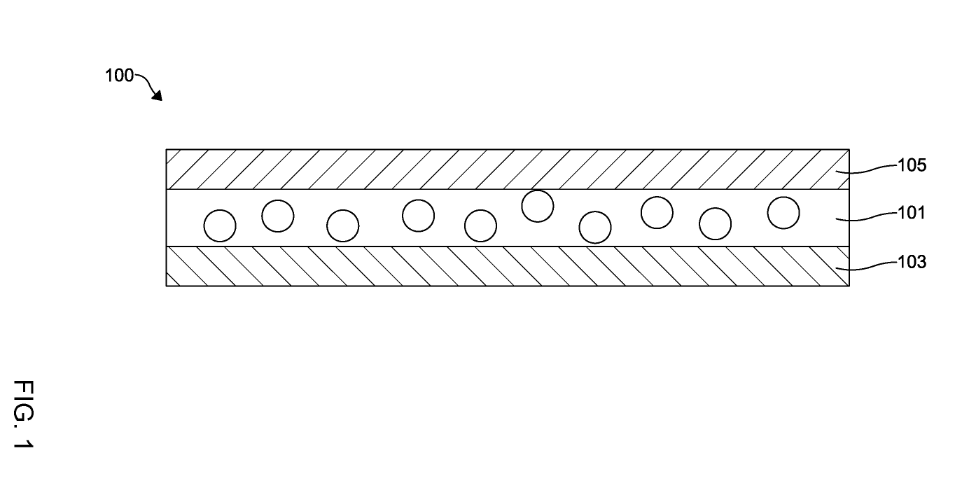

FIG. 2 is a schematic representation of a composite layered structure according to aspects of the present disclosure.

FIG. 3 is a schematic representation of a composite layered structure according to aspects of the present disclosure.

FIG. 4 is a schematic representation of a composite layered structure according to aspects of the present disclosure.

FIG. 5 is a method flow diagram according to aspects of the present disclosure.

### DETAILED DESCRIPTION

The disclosure relates to quantum dot films and methods of forming quantum dot films having reduced manufacturing complexity and film thickness (e.g., less than 50 μm (micrometers, microns), less than 100 micron, or other endpoint thicknesses between 5 microns and 50 microns (or about 5 μm and about 50 μm) or between 5 microns and 100 microns (or between about 5 μm and 100 μm)), among other aspects. A protective layer may be disposed adjacent a quantum dot layer to protect the quantum dot layer from oxygen and moisture. As an example, a barrier layer of a conventional multi-layer film may be replaced with the protective layer of the present disclosure. The protective layer may include one or more layers. As an example, the protective layer may include a functional layer such as a diffuser layer. As a further example, the protective layer may include an inorganic layer or a hybrid layer. Other configurations may be used as the protective layer, as described herein. While the present disclosure is not so limited, an appreciation of various aspects of the disclosure will be gained through a discussion of the examples provided below.

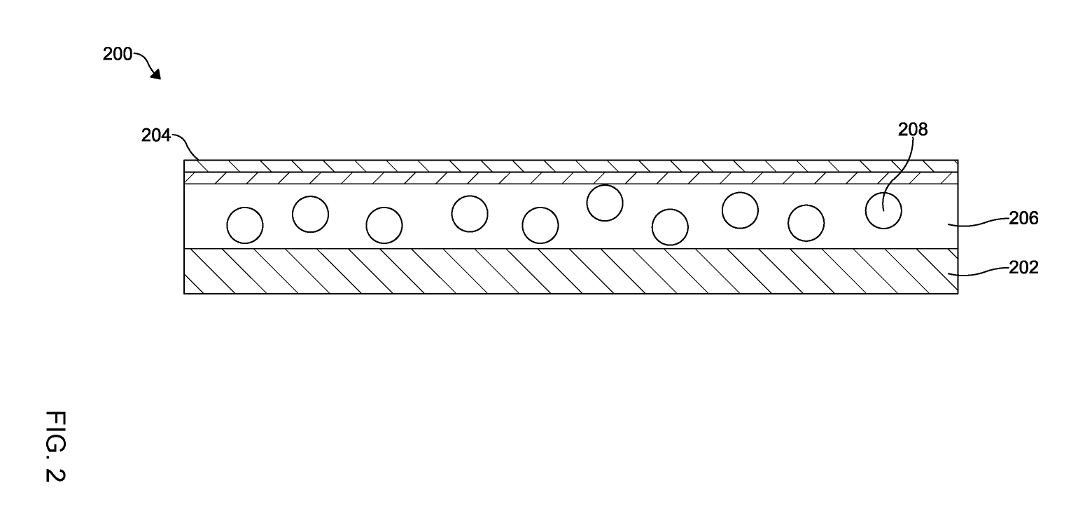

FIG. 2 is a schematic side elevation view of an illustrative quantum dot (QD) film 200. In one or more embodiments, the QD film 200 includes a barrier layer 202, a protective layer 204, and a quantum dot layer 206 disposed between the barrier layer 202 and the protective layer 204.

The quantum dot layer 206 may include quantum dots dispersed in a polymer material such as acryl type, epoxy type, or silicone type polymers, or combinations thereof. The quantum dot layer 206 may include one or more populations of quantum dots or quantum dot material 208. Exemplary quantum dots or quantum dot material emit green light and red light upon down-conversion of blue primary light from the blue LED to secondary light emitted by the quantum dots. The respective portions of red, green, and blue light may be controlled to achieve a desired white point for the white light emitted by a display device incorporating the quantum dot film article. Suitable quantum dots for use in quantum dot film articles described herein include core/shell luminescent nanocrystals including cadmium selenide/zinc sulfide (CdSe/ZnS), indium phosphide/zinc sulfide (InP/ZnS), lead selenide/lead sulfide (PbSe/PbS), (cadmium selenide/cadmium sulfide) CdSe/CdS, cadmium telluride/cadmium sulfide (CdTe/CdS) or cadmium telluride/zinc sulfide CdTe/ZnS. The quantum dot layer 206 may have any useful amount of quantum dots. In many embodiments the quantum dot layer may have from 0.05 weight percent (wt %) to 5 wt %, or from about 0.05 wt % to about 5 wt %, quantum dots. It is understood that various intervening endpoints in the proposed size ranges may be used. However, other loadings of quantum dots may be used.

In certain examples, the quantum dot layer 206 may include scattering beads or particles (not shown). The inclusion of scattering particles may result in a longer optical path length and improved quantum dot absorption and efficiency. The particle size is in a range from 50 nanometers (nm) to 10 micrometers (or from about 50 nm to about 10 μm), or from 100 nm to 6 micrometers (or from about 100 nm to about 6 μm). It is understood that various intervening endpoints in the proposed size ranges may be used. The quantum dot layer 206 may include fillers such as, but not limited to, fumed silica.

The barrier layer 202 may be formed of any useful film material that may protect the quantum dots from environmental conditions such as oxygen and moisture. Suitable barrier films include polymers, glass or dielectric materials, for example. Suitable barrier layer materials include, but are not limited to, polymers such as polyethylene terephthalate (PET); oxides such as silicon oxide (silicon dioxide, disilicon trioxide), titanium oxide, or aluminum oxide (e.g., SiO₂, Si₂O₃, TiO₂, or Al₂O₃); and suitable combinations thereof.

The barrier layer 202 of the QD film 200 may include at least two layers of different materials or compositions, such that the multi-layered barrier eliminates or reduces pinhole defect alignment in the barrier layer, providing an effective barrier to oxygen and moisture penetration into the quantum dot layer 206. The QD film 200 may include any suitable material or combination of materials and any suitable number of barrier layers on either or both sides of the quantum dot layer 206.

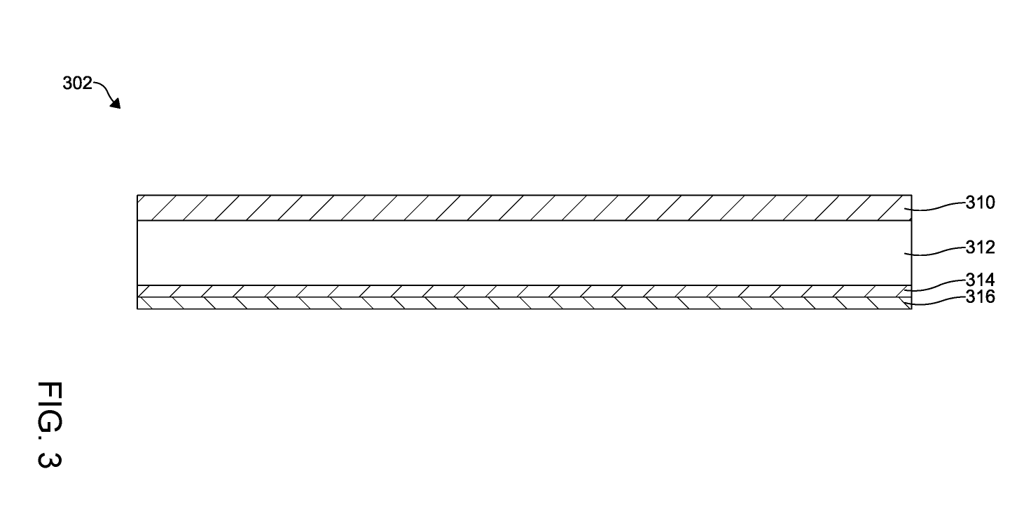

FIG. 3 illustrates an example barrier layer 302, which may be embodied as the barrier layer 202 (FIG. 2). As shown, the barrier layer 302 may include a diffuser layer 310 disposed on a base substrate 312 (e.g., a polymer). An inorganic layer 314 may be disposed on the substrate 312 opposite the diffuser layer 310. The inorganic layer 314 may include inorganic material such, for example, as a polysilazane-based polymer or a polysiloxane-based polymer. The inorganic layer may include oxides such as silicon oxide, titanium oxide, or aluminum oxide (e.g., SiO₂, Si₂O₃, TiO₂, or Al₂O₃); and suitable combinations thereof. In certain aspects, a coating 316 may be applied, for example, adjacent the inorganic layer 314. The coating 316 may be an adhesive coating (e.g., an organic layer) and may improve adhesion properties with a QD layer (see FIG. 2, QD layer 206), for example.

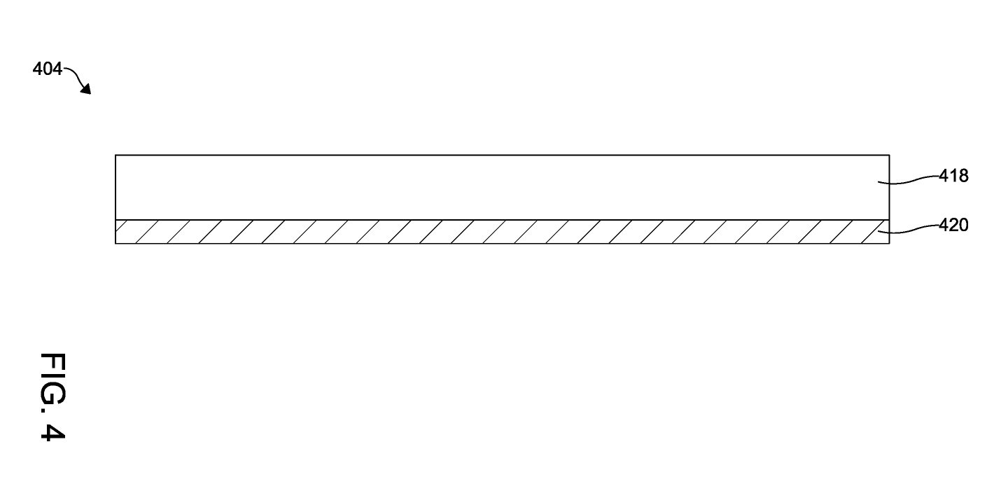

FIG. 4 illustrates an example protective layer 404, which may be embodied as the protective layer 204 (FIG. 2). As shown, the protective layer 404 may include a first functional layer 418 and a second layer 420 disposed adjacent the first functional layer 418.

The first functional layer 418 may be or include a diffuser layer. However, other functional layers may be used such as surface matt treatment and/or scratch resistant treatment. The second layer 420 may include an inorganic layer or hybrid inorganic/organic layers. Various inorganic materials may be used. As an example, the second layer 420 may include inorganic material such as a polysilazane-based polymer, a polysiloxane-based polymer.

The protective layer 404 may effectively prevent permeation of moisture and oxygen (e.g., exhibiting water vapor transmission rate (WVTR) of 10⁻¹-10⁻³ grams per square meter per day (g/m² day) as measured by ISO 15106-3 (second layer 420 comprising polysilozane, with a thickness of less than 1 micron) In addition, the protective layer 404 may be formed produced by low temperature wet processes. As an example, a low temperature wet process may include coating the first functional layer 418 with a material to form the second layer 420 and curing the resulting material (e.g., ultraviolet UV curing).

As an illustrative example, ultraviolet (UV) curing may be performed in a gastight aluminum casing equipped with low pressure mercury lamps (Hg LP; Heraeus Noblelight NIQ 65XL). The lamps may be configured to emit in the UV domain at about 254 nm (20 watts, W) and in the vacuum UV (VUV) domain at about 185 nm (5 W) with a distance to the sample at 20 millimeters (mm). A gas sweeping may be applied and may include a mixture of 99.9% pure dry nitrogen and 5% oxygen gas O₂ in dry nitrogen. Before beginning the curing of the sample, atmosphere may be purged with nitrogen during 10 minutes (8 liters per minute, L/min) and lamps may be allowed to heat to nominal power. The curing may occur with a partial pressure of oxygen at the surface of the sample inferior or equal to 1%.

As another illustrative example, the conversion of material may be represented by the reactions below:

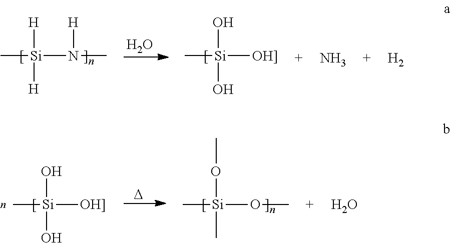

As described herein, the second layer 420 may include hybrid (inorganic/organic) material. As an example, the hybrid material may have the following structure:

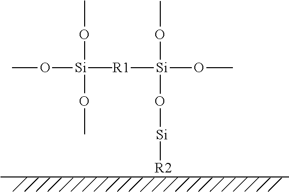

where R1 is an organic part that may offer flexibility; and

where R2 is the other organic part that may improve the adhesion property.

A surface of a solid plastic form including a filler, a polyester, or a combination thereof, may be coated with a flowable curable coating composition. As an example, the protective layer according to aspects of the present disclosure may be or comprise a flowable curable coating composition as described herein. As such, the flowable curable coating composition may be used to coat a surface such as a quantum dot layer of a film.

The curable coating composition may be cured to provide a hardened film on the solid plastic form surface. The hardened film may provide a hard an abrasion resistant coating layer. The hardened film may provide high surface hardness and a glass-like feel, and may provide a desirable combination of properties such as hardness, scratch resistance, mechanical strength, and impact resistance. The filler, polyester, or combination thereof, may produce a surprising increase in hardness as compared to the results of the treatment as performed on a solid plastic form free of filler and polyester.

The method may include coating a surface of a solid plastic form with a flowable curable coating composition. The coating may be performed in any suitable manner that forms a coating of the flowable curable coating composition on a surface of the solid plastic form. Wet or transfer coating methods may be used. For example, the coating may be bar coating, spin coating, spray coating, or dipping. Single- or multiple-side coating may be performed.

The solid plastic form may be transparent, opaque, or any one or more colors. The solid plastic form may include any one or more suitable plastics (e.g., as a homogeneous mixture of plastics). In some embodiments, the solid plastic form may include at least one of an acrylonitrile butadiene styrene (ABS) polymer, an acrylic polymer, a celluloid polymer, a cellulose acetate polymer, a cycloolefin copolymer (COC), an ethylene-vinyl acetate (EVA) polymer, an ethylene vinyl alcohol (EVOH) polymer, a fluoroplastic, an ionomer, an acrylic/PVC alloy, a liquid crystal polymer (LCP), a polyacetal polymer (POM or acetal), a polyacrylate polymer, a polymethylmethacrylate polymer (PMMA), a polyacrylonitrile polymer (PAN or acrylonitrile), a polyamide polymer (PA or nylon), a polyamide-imide polymer (PAI), a polyaryletherketone polymer (PAEK) a polybutadiene polymer (PBD), a polybutylene polymer (PB), a polybutylene terephthalate polymer (PBT), a polycaprolactone polymer (PCL), a polychlorotrifluoroethylene polymer (PCTFE), a polytetrafluoroethylene polymer (PTFE), a polyethylene terephthalate polymer (PET), a polycyclohexylene dimethylene terephthalate polymer (PCT), a polycarbonate polymer (PC), a polyhydroxyalkanoate polymer (PHA), a polyketone polymer (PK), a polyester polymer, a polyethylene polymer (PE), a polyetheretherketone polymer (PEEK), a polyetherketoneketone polymer (PEKK), a polyetherketone polymer (PEK), a polyetherimide polymer (PEI), a polyethersulfone polymer (PES), a polyethylenechlorinate polymer (PEC), a polyimide polymer (PI), a polylactic acid polymer (PLA), a polymethylpentene polymer (PMP), a polyphenylene oxide polymer (PPO), a polyphenylene sulfide polymer (PPS), a polyphthalamide polymer (PPA), a polypropylene polymer, a polystyrene polymer (PS), a polysulfone polymer (PSU), a polytrimethylene terephthalate polymer (PTT), a polyurethane polymer (PU), a polyvinyl acetate polymer (PVA), a polyvinyl chloride polymer (PVC), a polyvinylidene chloride polymer (PVDC), a polyamideimide polymer (PAI), a polyarylate polymer, a polyoxymethylene polymer (POM), and a styrene-acrylonitrile polymer (SAN). In some embodiments, the solid plastic form includes at least one of polycarbonate polymer (PC) and polymethylmethacrylate polymer (PMMA). The solid plastic form may include a blend of PC and PMMA.

The solid plastic form may include one type of polycarbonate or multiple types of polycarbonate. The polycarbonate may be made via interfacial polymerization (e.g., reaction of bisphenol with phosgene at an interface between an organic solution such as methylene chloride and a caustic aqueous solution) or melt polymerization (e.g., transesterification and/or polycondensation of monomers or oligomers above the melt temperature of the reaction mass). Although the reaction conditions for interfacial polymerization may vary, in an example the procedure may include dissolving or dispersing a dihydric phenol reactant in aqueous caustic soda or potash, adding the resulting mixture to a suitable water-immiscible solvent medium, and contacting the reactants with a carbonate precursor (e.g., phosgene) in the presence of a catalyst such as triethylamine or a phase transfer catalyst, under controlled pH conditions, e.g., 8 to 10, or about 8 to about 10. The most commonly used water-immiscible solvents include methylene chloride, 1,2-dichloroethane, chlorobenzene, toluene, and the like.

Alternatively, melt processes may be used to make the polycarbonates. Generally, in the melt polymerization process, polycarbonates may be prepared by co-reacting, in a molten state, the dihydroxy reactant(s) and a diaryl carbonate ester, such as diphenyl carbonate, in the presence of a transesterification catalyst in a mixer, twin screw extruder, or the like, to form a uniform dispersion. Volatile monohydric phenol may be removed from the molten reactants by distillation and the polymer may be isolated as a molten residue. In some embodiments, a melt process for making polycarbonates uses a diaryl carbonate ester having electron-withdrawing substituents on the aryl groups, such as bis(4-nitrophenyl)carbonate, bis(2-chlorophenyl)carbonate, bis(4-chlorophenyl)carbonate, bis(methyl salicyl)carbonate, bis(4-methylcarboxylphenyl)carbonate, bis(2-acetylphenyl)carboxylate, bis(4-acetylphenyl)carboxylate, or a combination thereof. In addition, transesterification catalysts for use may include phase transfer catalysts such as tetrabutylammonium hydroxide, methyltributylammonium hydroxide, tetrabutylammonium acetate, tetrabutylphosphonium hydroxide, tetrabutylphosphonium acetate, tetrabutylphosphonium phenolate, or a combination thereof.

The one or more polycarbonates may be 50 wt % to 100 wt % or about 50 wt % to about 100 wt % of the solid plastic form, such as about 50 wt % or less, or about 55 wt %, 60, 65, 70, 75, 80, 85, 90, 95, 96, 97, 98, 99, 99.9 wt %, or about 99.99 wt % or more. In various embodiments, the polycarbonate may include a repeating group having the structure:

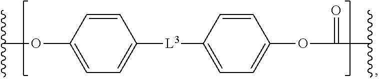

Each phenyl ring in the structure is independently substituted or unsubstituted. The variable L³ is chosen from —S(O)₂— and substituted or unsubstituted (C₁-C₂₀)hydrocarbylene. In various embodiments, the polycarbonate may be derived from bisphenol A, such that the polycarbonate includes a repeating group having the structure:

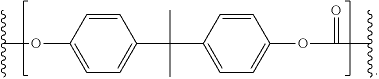

The solid plastic form may include a filler, such as one filler or multiple fillers. The filler may be any suitable type of filler. The filler may be homogeneously distributed in the solid plastic form. The one or more fillers may form about 0.001 wt % to about 50 wt % of the solid plastic form, or 0.01 wt % to 30 wt % or from about 0.01 wt % to about 30 wt %, or about 0.001 wt % or less, or about 0.01 wt %, 0.1, 1, 2, 3, 4, 5, 10, 15, 20, 25, 30, 35, 40, 45 wt %, or about 50 wt % or more. The filler may be fibrous or particulate. The filler may be aluminum silicate (mullite), synthetic calcium silicate, zirconium silicate, fused silica, crystalline silica graphite, natural silica sand, or the like; boron powders; oxides such as TiO₂, aluminum oxide, magnesium oxide, or the like; calcium sulfate (as its anhydride, dehydrate or trihydrate); calcium carbonates such as chalk, limestone, marble, synthetic precipitated calcium carbonates, or the like; talc, including fibrous, modular, needle shaped, lamellar talc, or the like; wollastonite; surface-treated wollastonite; glass spheres such as hollow and solid glass spheres; kaolin; single crystal fibers or “whiskers” such as silicon carbide, alumina, boron carbide, iron, nickel, copper, or the like; fibers (including continuous and chopped fibers) such as asbestos, carbon fibers, glass fibers; sulfides such as molybdenum sulfide, zinc sulfide, or the like; barium compounds; metals and metal oxides such as particulate or fibrous materials; flaked fillers; fibrous fillers, for example short inorganic fibers such as those derived from blends including at least one of aluminum silicates, aluminum oxides, magnesium oxides, and calcium sulfate hemihydrate or the like; natural fillers and reinforcements; organic fillers such as polytetrafluoroethylene, reinforcing organic fibrous fillers formed from organic polymers capable of forming fibers such as poly(ether ketone), polyimide, polybenzoxazole, poly(phenylene sulfide), polyesters, polyethylene, aromatic polyamides, aromatic polyimides, polyetherimides, polytetrafluoroethylene, acrylic resins, poly(vinyl alcohol) or the like; or combinations including at least one of the foregoing fillers. The filler may be selected from glass fibers, carbon fibers, a mineral fillers, or combinations thereof. The filler may be glass fibers.

The glass fibers may be selected from E-glass, S-glass, AR-glass, T-glass, D-glass, R-glass, and combinations thereof. The glass fibers used may be selected from E-glass, S-glass, and combinations thereof. High-strength glass is generally known as S-type glass in the United States, R-glass in Europe, and T-glass in Japan. High-strength glass has appreciably higher amounts of silica oxide, aluminum oxide and magnesium oxide than E-glass. S-2 glass is approximately 40-70% stronger than E-glass. The glass fibers may be made by standard processes, e.g., by steam or air blowing, flame blowing, and mechanical pulling.

The glass fibers may be sized or unsized. Sized glass fibers are coated on their surfaces with a sizing composition selected for compatibility with the polycarbonate. The sizing composition facilitates wet-out and wet-through of the polycarbonate on the fiber strands and assists in attaining desired physical properties in the polycarbonate composition. The glass fibers may be sized with a coating agent. The coating agent may be present in an amount from 0.1 wt % to 5 wt % or from about 0.1 wt % to about 5 wt %, or 0.1 wt % to 2 wt % or from about 0.1 wt % to about 2 wt %, based on the weight of the glass fibers.

In preparing the glass fibers, a number of filaments may be formed simultaneously, sized with the coating agent and then bundled into what is called a strand. Alternatively the strand itself may be first formed of filaments and then sized. The amount of sizing employed is generally that amount which is sufficient to bind the glass filaments into a continuous strand and may be 0.1 wt % to 5 wt % or from about 0.1 to about 5 wt %, 0.1 wt % to 2 wt % or from about 0.1 to 2 wt %, or 1 wt % or about 1 wt %, based on the weight of the glass fibers.

The glass fibers may be continuous or chopped. Glass fibers in the form of chopped strands may have a length of 0.3 mm to 10 cm or about 0.3 mm to about 10 cm, 0.5 cm to 5 cm or about 0.5 cm to about 5 cm, 1.0 mm to 2.5 cm or about 1.0 mm to about 2.5 cm. In various further aspects, the glass fibers may have a length of 0.2 mm to 20 mm or about 0.2 mm to about 20 mm, of 0.2 mm to 10 mm or about 0.2 mm to about 10 mm, or 0.7 mm to 7 mm or about 0.7 mm to about 7 mm, 1 mm or longer, or 2 mm or longer. The glass fibers may have a round (or circular), flat, or irregular cross-section. The diameter of the glass fibers may be 1 μm to 15 μm or about 1 μm to about 15 μm, 4 μm to 10 μm about 4 μm to about 10 μm, 1 μm to 10 μm or about 1 μm to about 10 μm, or 7 μm to 10 μm or about 7 μm to about 10 μm.

The solid plastic form may include a polyester. The polyester may be any suitable polyester. The polyester may be chosen from aromatic polyesters, poly(alkylene esters) including poly(alkylene arylates) (e.g., poly(alkylene terephthalates)), and poly(cycloalkylene diesters) (e.g., poly(cycloghexanedimethylene terephthalate) (PCT), or poly(1,4-cyclohexane-dimethanol-1,4-cyclohexanedicarboxylate) (PCCD)), and resourcinol-based aryl polyesters. The polyester may be poly(isophthalate-terephthalate-resorcinol)esters, poly(isophthalate-terephthalate-bisphenol A)esters, poly[(isophthalate-terephthalate-resorcinol)ester-co-(isophthalate-terephthalate-bisphenol A)]ester, or a combination including at least one of these. Examples of poly(alkylene terephthalates) include poly(ethylene terephthalate) (PET), poly(1,4-butylene terephthalate) (PBT), and poly(propylene terephthalate) (PPT). Also useful are poly(alkylene naphthoates), such as poly(ethylene naphthanoate) (PEN), and poly(butylene naphthanoate) (PBN). Copolymers including alkylene terephthalate repeating ester units with other ester groups may also be useful. Useful ester units may include different alkylene terephthalate units, which may be present in the polymer chain as individual units, or as blocks of poly(alkylene terephthalates). Specific examples of such copolymers include poly(cyclohexanedimethylene terephthalate)-co-poly(ethylene terephthalate), abbreviated as PETG where the polymer includes greater than or equal to 50 mol % of poly(ethylene terephthalate), and abbreviated as PCTG where the polymer includes greater than 50 mol % of poly(1,4-cyclohexanedimethylene terephthalate). The polyester may be substantially homogeneously distributed in the solid plastic form. The solid plastic form may include one type of polyester or multiple types of polyester. The one or more polyesters may form any suitable proportion of the solid plastic form, such as 0.001 wt % to 50 wt % or about 0.001 wt % to about 50 wt % of the solid plastic form, 0.01 wt. % to 30 wt % or about 0.01 wt % to about 30 wt %, or 0.001 wt % or about 0.001 wt % or less, or about 0.01 wt %, 0.1, 1, 2, 3, 4, 5, 6, 8, 10, 12, 14, 16, 18, 20, 22, 24, 26, 28, 30, 35, 40, 45 wt %, or about 50 wt % or more. The polyester may include a repeating unit having the structure:

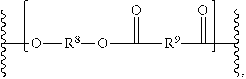

The variables R⁸ and R⁹ may be independently substituted or unsubstituted (C₁-C₂₀)hydrocarbylene. The variables R⁸ and R⁹ may be cycloalkylene-containing groups or aryl-containing groups. The variables R⁸ and R⁹ may be independently substituted or unsubstituted phenyl, or substituted or unsubstituted —(C₀-C₁₀)hydrocarbyl-(C₄-C₁₀)cycloalkyl-(C₀-C₁₀)hydrocarbyl-. The variables R⁸ and R⁹ may both be cycloalkylene-containing groups. The variables R⁸ and R⁹ may independently have the structure:

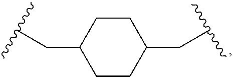 [SMILES: *CC1CCC(C*)CC1]

wherein the cyclohexylene may be substituted in a cis or trans fashion. In some examples, R9 may be a para-substituted phenyl, such that R⁹ appears in the polyester structure as:

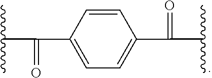 [SMILES: *C(=O)c1ccc(C(*)=O)cc1]

The solid plastic form may have any suitable shape and size. In some embodiments, the solid plastic form is a sheet having any suitable thickness, such as a thickness of about 25 microns to about 50,000 microns, about 25 microns to about 15,000 microns, about 60 microns to about 800 microns, or about 25 microns or less, or about 50, 75, 100, 150, 200, 250, 300, 400, 500, 600, 700, 800, 900, 1,000, 1,500, 2,000, 3,000, 4,000, 5,000, 6,000, 8,000, 10,000, 12,000, 14,000, 15,000, 20,000, 25,000, 30,000, 40,000, or about 50,000 microns or more.

The flowable curable coating composition may include a) an alicyclic epoxy group-containing siloxane resin having a weight average molecular weight of about 1,000 to about 4,000 and a (M_{w}/Mₙ) of about 1.05 to about 1.4, b) an epoxy-functional organosiloxane and an organosiloxane comprising a isocyanate group or an isocyanurate group, or both a) and b).

The epoxy-functional organosiloxane may have the structure:

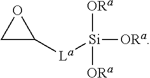

At each occurrence, R may be independently substituted or unsubstituted (C₁-C₁₀)alkyl. At each occurrence, the variable R may be independently unsubstituted (C₁-C₆)alkyl. The variable L^{a} may be substituted or unsubstituted (C₁-C₃₀)hydrocarbyl interrupted by 0, 1, 2, or 3 groups independently chosen from —O—, —S—, substituted or unsubstituted —NH—, —(Si(OR^{a})₂)ₙ₁—, —(O—CH₂—CH₂)ₙ₁—, and —(O—CH₂—CH₂—CH₂)ₙ₁—, wherein n1 may be about 1 to about 1,000 (e.g., 1-100, 1-50, 1-10, 1, 2, 3, 4, 5, 6, 8, 10, 12, 14, 16, 18, 20, 25, 30, 40, 50, 75, 100, 200, 250, 500, 750, 1,000). The variable L^{a} may be an unsubstituted (C₁-C₃₀)hydrocarbyl interrupted by 0, 1, 2, or 3 groups independently chosen from —O— and —S—. The epoxy-functional organosiloxane may be 2-(3,4-epoxycyclohexyl)ethyltrimethoxysilane, 3-glycidoxypropyl methyldimethoxysilane, 3-glycidoxypropyl trimethoxysilane, 3-glycidoxypropyl methyldiethoxysilane, or 3-glycidoxypropyl triethoxysilane. The flowable curable resin composition may include one epoxy-functional organosiloxane, or multiple epoxy-functional organosiloxanes. The one or more epoxy-functional organosiloxanes may be any suitable proportion of the flowable curable resin composition such as 0.01 wt % to 100 wt % or about 0.01 wt % to about 100 wt %, 10 wt % to 100 wt % or about 10 wt % to about 100 wt %, 50 wt % to 99.9 wt % or about 50 wt % to about 99.9 wt %, or 0.01 wt % or about 0.01 wt % or less, or about 0.1 wt %, 1, 2, 3, 4, 5, 6, 8, 10, 12, 14, 15, 20, 25, 30, 35, 40, 45, 50, 55, 60, 65, 70, 75, 80, 85, 90, 95, 96, 97, 98, 99, 99.9, or about 99.99 wt %.

The organosiloxane including an isocyanate group may have the structure (R^{b})₄₋ₚSi(R^{c})ₚ. The variable p may be 1 to 4 (e.g., 1, 2, 3, or 4). At each occurrence, R^{b} may be independently chosen from substituted or unsubstituted (C₁-C₁₀)alkyl and substituted or unsubstituted (C₁-C₁₀)alkoxy. At each occurrence, R^{b} may be independently chosen from unsubstituted (C₁-C₆)alkyl and unsubstituted (C₁-C₆)alkoxy. At each occurrence, R^{c} may be -L^{b}-NCO, wherein L^{b} may be a substituted or unsubstituted (C₁-C₃₀)hydrocarbyl interrupted by 0, 1, 2, or 3 groups independently chosen from —O—, —S—, substituted or unsubstituted —NH—, —(Si(OR^{b})₂)ₙ₂—, —(O—CH₂—CH₂)ₙ₂—, and —(O—CH₂—CH₂—CH₂)ₙ₂—, wherein n2 may be about 1 to about 1,000 (e.g., 1-100, 1-50, 1-10, 1, 2, 3, 4, 5, 6, 8, 10, 12, 14, 16, 18, 20, 25, 30, 40, 50, 75, 100, 200, 250, 500, 750, 1,000). At each occurrence, L^{c} may be an unsubstituted (C₁-C₃₀)hydrocarbyl interrupted by 0, 1, 2, or 3 groups independently chosen from —O— and —S—. The organosiloxane including the isocyanate group may be 3-isocyanatepropyltriethoxysilane. The flowable curable resin composition may include one or more than one organosiloxane including an isocyanate group. The one or more organosiloxanes including an isocyanate group may form any suitable proportion of the flowable curable resin composition, such as 0.01 wt % to 100 wt % or about 0.01 wt % to about 100 wt %, 10 wt % to 100 wt % or about 10 wt % to about 100 wt %, 50 wt % to 99.9 wt % or about 50 wt % to about 99.9 wt %, or 0.01 wt % or about 0.01 wt % or less, or about 0.1 wt %, 1, 2, 3, 4, 5, 6, 8, 10, 12, 14, 15, 20, 25, 30, 35, 40, 45, 50, 55, 60, 65, 70, 75, 80, 85, 90, 95, 96, 97, 98, 99, 99.9, or about 99.99 wt %.

The organosiloxane including an isocyanurate group may have the structure:

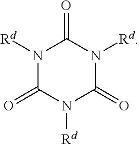

At each occurrence, R^{d} may be chosen from —H and -L^{c}-Si(R^{e})₃, wherein at least one R^{d} is -L^{c}-Si(R^{e})₃. At each occurrence, R^{d} may be -L^{c}-Si(R^{e})₃. At each occurrence, L^{c} may be independently a substituted or unsubstituted (C₁-C₃₀)hydrocarbyl interrupted by 0, 1, 2, or 3 groups independently chosen from —O—, —S—, substituted or unsubstituted —NH—, —(Si(R^{e})₂)ₙ₃—, —(O—CH₂—CH₂)ₙ₃—, and —(O—CH₂—CH₂—CH₂)ₙ₃—, wherein n3 may be about 1 to about 1,000 (e.g., 1-100, 1-50, 1-10, 1, 2, 3, 4, 5, 6, 8, 10, 12, 14, 16, 18, 20, 25, 30, 40, 50, 75, 100, 200, 250, 500, 750, 1,000). At each occurrence, L^{c} may be an unsubstituted (C₁-C₃₀)hydrocarbyl interrupted by 0, 1, 2, or 3 groups independently chosen from —O— and —S—. At each occurrence, R^{e} may be chosen from substituted or unsubstituted (C₁-C₁₀)alkyl and substituted or unsubstituted (C₁-C₁₀)alkoxy. At each occurrence, R may be independently chosen from unsubstituted (C₁-C₆)alkyl and unsubstituted (C₁-C₆)alkoxy. The organosiloxane including the isocyanate group or isocyanurate group may be tris-[3-(trimethoxysilyl propyl)-isocyanurate. The flowable curable resin composition may include one or multiple organosiloxanes including an isocyanurate group. Any suitable proportion of the flowable curable resin composition may be the one or more organosiloxanes including an isocyanurate group, such as 0.01 wt % to 100 wt % or about 0.01 wt % to about 100 wt %, 10 wt % to 100 wt % or about 10 wt % to about 100 wt %, 50 wt % to 99.9 wt % or about 50 wt % to about 99.9 wt %, or 0.01 wt % or about 0.01 wt % or less or about 0.1 wt %, 1, 2, 3, 4, 5, 6, 8, 10, 12, 14, 15, 20, 25, 30, 35, 40, 45, 50, 55, 60, 65, 70, 75, 80, 85, 90, 95, 96, 97, 98, 99, 99.9, or about 99.99 wt %.

The flowable curable resin composition may include a bis(organosiloxane)-functional amine. In some embodiments, the flowable curable resin composition includes an epoxy-functional organosiloxane, an organosiloxane comprising a isocyanate group or an isocyanurate group, and a bis(organosiloxane)-functional amine. The bis(organosiloxane)-functional amine may have the structure R^{f}₃Si-L^{d}-NH-L^{d}-SiR^{f}₃. At each occurrence, R^{f} may be chosen from substituted or unsubstituted (C₁-C₁₀)alkyl and substituted or unsubstituted (C₁-C₁₀)alkoxy. At each occurrence, R^{f} may be independently chosen from unsubstituted (C₁-C₆)alkyl and unsubstituted (C₁-C₆)alkoxy. At each occurrence, L^{d} may be independently a substituted or unsubstituted (C₁-C₃₀)hydrocarbyl interrupted by 0, 1, 2, or 3 groups independently chosen from —O—, —S—, substituted or unsubstituted —NH—, —(Si(R^{f})₂)ₙ₄—, —(O—CH₂—CH₂)ₙ₄—, and —(O—CH₂—CH₂—CH₂)ₙ₄—, wherein n4 may be about 1 to about 1,000 (e.g., 1-100, 1-50, 1-10, 1, 2, 3, 4, 5, 6, 8, 10, 12, 14, 16, 18, 20, 25, 30, 40, 50, 75, 100, 200, 250, 500, 750, 1,000). At each occurrence, L^{d} may be an unsubstituted (C₁-C₃₀)hydrocarbyl interrupted by 0, 1, 2, or 3 groups independently chosen from —O— and —S—. The bis(organosiloxane)-functional amine may be bis(triethoxysilylpropyl)amine, bis(trimethoxysilylpropyl)amine, or bis(methyldiethoxysilylpropyl) amine. The flowable curable resin composition may include one or more bis(organosiloxane)-functional amines. The one or more bis(organosiloxane)-functional amines may form any suitable proportion of the flowable curable resin composition, such as 0.01 wt % to 100 wt % or about 0.01 wt % to about 100 wt %, 10 wt % to 100 wt % or about 10 wt % to about 100 wt %, 50 wt % to 99.9 wt % or about 50 wt % to about 99.9 wt %, or 0.01 wt % or about 0.01 wt % or less, or about 0.1 wt %, 1, 2, 3, 4, 5, 6, 8, 10, 12, 14, 15, 20, 25, 30, 35, 40, 45, 50, 55, 60, 65, 70, 75, 80, 85, 90, 95, 96, 97, 98, 99, 99.9, or about 99.99 wt %.

The method may include performing a hydrolysis and condensation reaction using water and a catalyst to form a sol (e.g., colloidal suspension), releasing alcohol or water. The sol may include the flowable curable resin composition. Coating the surface of the solid plastic form may include coating the solid plastic form with the sol. Curing the curable coating composition may include curing the sol on the plastic form, to provide the hardened film (e.g., gel) on the solid plastic form surface.

The flowable curable coating composition may include an alicyclic epoxy group-containing siloxane resin. The flowable curable coating composition may include one type of alicyclic epoxy group-containing siloxane resin or multiple types of such resin. The one or more alicyclic epoxy group-containing siloxane resin may form any suitable proportion of the flowable curable coating composition, such as 0.01 wt % to 100 wt % or about 0.01 wt % to about 100 wt %, 10 wt % to 100 wt % or about 10 wt % to about 100 wt %, 50 wt % to 99.9 wt % or about 50 wt % to about 99.9 wt %, or 0.01 wt % or about 0.01 wt % or less, or about 0.1 wt %, 1, 2, 3, 4, 5, 6, 8, 10, 12, 14, 15, 20, 25, 30, 35, 40, 45, 50, 55, 60, 65, 70, 75, 80, 85, 90, 95, 96, 97, 98, 99, 99.9, or about 99.99 wt %. The siloxane resin may have a weight average molecular weight of about 1,000 to about 4,000 (e.g., about 1,000, 1,200, 1,400, 1,600, 1,800, 2,000, 2,200, 2,400, 2,600, 2,800, 3,000, 3,200, 3,400, 3,600, 3,800, or 4,000) and a (M_{w}/Mₙ) (i.e., weight average molecular weight divided by number average molecular weight, also referred to as polydispersity, a measure of the heterogeneity of sizes of molecules in the mixture) of about 1.05 to about 1.4 (e.g., about 1.05, 1.2, 1.4, 1.6, 1.8, 2.0, 2.2, 2.4, 2.6, 2.8, 3.0, 3.2, 3.4, 3.6, 3.8, or about 4.0 or more).

The siloxane resin may be prepared by hydrolysis and condensation, in the presence of water and an optional catalyst, of (i) an alkoxysilane including an alicyclic epoxy group and an alkoxy group having the structure R¹ₙSi(OR²)₄₋ₙ alone, wherein R¹ is (C₃-C₆)cycloalkyl(C₁-C₆)alkyl wherein the cycloalkyl group includes an epoxy group, R² is (C1-C7)alkyl, and n is 1-3, or (ii) the alkoxysilane having the structure R¹ₙSi(OR²)₄₋ₙ and an alkoxysilane having the structure R³ₘSi(OR)₄₋ₘ, wherein R³ is chosen from (C₁-C₂₀)alkyl, (C₃-C₈)cycloalkyl, (C₂-C₂₀)alkenyl, (C₂-C₂₀)alkynyl, (C₆-C₂₀)aryl, an acryl group, a methacyl group, a halogen group, an amino group, a mercapto group, an ether group, an ester group, a carbonayl group, a carboxyl group, a vinyl group, a nitro group, a sulfone group, and an alkyd group, R⁴ is (C₁-C₇)alkyl, and m is 0 to 3. The alkoxysilxane having the structure R¹ₙSi(OR²)₄₋ₙ may be 2-(3,4-epoxycyclohexyl)ethyltrimethoxysilane or 2-(3,4-epoxycyclohexyl)ethyltriethoxysilane. The alkoxysilane having the structure R³ₘSi(OR⁴)₄₋ₘ may be one or more chosen from tetramethoxysilane, tetraethoxysilane, methyltrimethoxysilane, methyltriethoxysilane, methyltripropoxysilane, dimethyldimethoxysilane, dimethyldiethoxysilane, phenyltrimethoxysilane, phenyltriethoxysilane, diphenyldimethoxysilane, diphenyldiethoxysilane, triphenylmethoxysilane, triphenylethoxysilane, ethyltriethoxysilane, propylethyltrimethoxysilane, vinyltrimethoxysilane, vinyltriethoxysilane, vinyltripropoxysilane, N-(3-acryloxy-2-hydroxypropyl)-3-aminopropyltrimethoxysilane, N-(3-acryloxy-2-hydroxypropyl)-3-aminopropyltriethoxysilane, N-(3-acryloxy-2-hydroxypropyl)-3-aminopropyltripropoxysilane, 3-acryloxypropylmethylbis (trimethoxy) silane, 3-acryloxypropyltrimethoxysilane, 3-acryloxypropyltriethoxysilane, 3-acryloxypropyltripropoxysilane, 3-(meth)acryloxypropyltrimethoxysilane, 3-(meth)acryloxypropyltriethoxysilane, 3-(meth)acryloxypropyltripropoxysilane, N-(aminoethyl-3-aminopropyl)trimethoxysilane, N-(2-aminoethyl-3-aminopropyl)triethoxysilane, 3-aminopropyltrimethoxysilane, 3-aminopropyltriethoxysilane, chloropropyltrimethoxysilane, chloropropyltriethoxysilane, and heptadecafluorodecyltrimethoxysilane.

The flowable curable coating composition may further include a reactive monomer capable of reacting with the alicyclic epoxy group to form crosslinking. The flowable curable coating composition may include one such monomer or multiple such monomers. The one or more reactive monomers may form any suitable proportion of the flowable curable coating composition, such as 0.001 wt % to 30 wt % or about 0.001 wt % to about 30 wt %, or 0.01 wt % to 10 wt % or about 0.01 wt % to about 10 wt %, or 0.001 wt % or about 0.001 wt % or less, or about 0.01 wt %, 0.1, 1, 2, 3, 4, 5, 6, 8, 10, 12, 14, 16, 18, 20, 22, 24, 26, 28, or about 30 wt % or more. The one or more reactive monomer may be present in any suitable weight ratio to the epoxy-containing siloxane resin, such as about 1:1000 to about 1:10, or about 1:1000 or less, or about 1:500, 1:250, 1:200, 1:150, 1:100, 1:80, 1:60, 1:40, 1:20, or about 1:10 or more. The reactive monomer may be an acid anhydride monomer, an oxetane monomer, or a monomer having an alicyclic epoxy group as a (C₃-C₆)cycloalkyl group. The acid anhydride monomer may be one or more chosen from phthalic anhydride, tetrahydrophthalic anhydride, hexahydrophthalic anhydride, nadic methyl anhydride, chlorendic anhydride, and pyromellitic anhydride. The oxetane monomer may be one or more chosen from 3-ethyl-3-hydroxymethyloxetane, 2-ethylhexyloxetane, xylene bis oxetane, and 3-ethyl-3[[3-ethyloxetan-3-yl]methoxy]oxetane. The reactive monomer having an alicyclic epoxy group may be one or more chosen from 4-vinylcycloghexene dioxide, cyclohexene vinyl monoxide, (3,4-epoxycyclohexyl)methyl 3,4-epoxycyclohexylcarboxylate, 3,4-epoxycyclohexylmethyl methacrylate, and bis(3,4-epoxycyclohexylmethyl)adipate.

In various embodiments, one or more catalysts are present. In other embodiments, the flowable curable coating composition may be free of catalyst. The catalyst may be any suitable catalyst, such as acidic catalysts, basic catalysts, ion exchange resins, and combinations thereof. For example, the catalyst may be hydrochloric acid, acetic acid, hydrogen fluoride, nitric acid, sulfuric acid, chlorosulfonic acid, iodic acid, pyrophosphoric acid, ammonia, potassium hydroxide, sodium hydroxide, barium hydroxide, imidazole, and combinations thereof.

The curable flowable coating composition may include one or more organic solvents, such as in an amount of 0.01 parts by weight to 10 parts by weight or about 0.01 to about 10 parts by weight, based on 100 parts by weight of the siloxane resin, or 0.1 parts by weight to 10 parts by weight or about 0.1 to about 10 parts by weight. The one or more solvents may be 0.001 wt % to 50 wt % or about 0.001 wt % to about 50 wt % of the curable flowable coating composition, 0.01 wt % to 30 wt % or about 0.01 wt % to about 30 wt %, 30 wt % to 70 wt % or about 30 wt % to about 70 wt %, or 0.001 wt % or about 0.001 wt % or less, or about 0.01 wt %, 0.1, 1, 2, 3, 4, 5, 6, 8, 10, 12, 14, 16, 18, 20, 22, 24, 26, 28, 30, 35, 40, 45 wt %, or about 50 wt % or more.

The flowable curable coating composition may further includes one or more polymerization initiators chosen from UV initiators, thermal initiators, onium salts, organometallic salts, amines, and imidazoles in an amount of about 0.01 to about 10 parts by weight, based on 100 parts by weight of the siloxane resin, or about 0.1 to about 10 parts by weight. The one or more polymerization initiators may be 0.001 wt % to 50 wt % or about 0.001 wt % to about 50 wt % of the curable flowable coating composition, 0.01 wt % to 30 wt % or about 0.01 wt % to about 30 wt %, or 0.001 wt % or about 0.001 wt % or less, or about 0.01 wt %, 0.1, 1, 2, 3, 4, 5, 6, 8, 10, 12, 14, 16, 18, 20, 22, 24, 26, 28, 30, 35, 40, 45 wt %, or about 50 wt % or more.

The flowable curable coating composition may further include one or more additives, such as chosen from an antioxidant, a leveling agent, an antifogging agent, an antifouling agent, and a coating control agent.

The method may also include curing the curable coating composition, to provide a hardened film on the solid plastic form surface. The curing may be any suitable curing. The curing may be thermal curing. The curing may be UV curing. The curing may be a combination of thermal and UV curing (e.g., in parallel or sequential).

The hardened film on the solid plastic form may have any suitable thickness, such as 1 micron to 1,000 microns or about 1 micron to about 1,000 microns, 1 micron to 100 micron or about 1 micron to about 100 microns, 5 microns to 75 microns about 5 microns to about 75 microns, or about 1 micron, 2, 3, 4, 5, 6, 8, 10, 12, 14, 16, 18, 20, 25, 30, 35, 40, 45, 50, 55, 60, 65, 70, 75, 80, 85, 90, 95, 100, 200, 500, 750, or about 1,000 microns or more.

The hardened film on the solid plastic form surface may have any suitable hardness. For example, the hardened film on the solid plastic form surface may have a hardness of about 3B to about 9H, or about HB to about 8H, or about 3B or less, or about 2B, B, HB, F, H, 2H, 3H, 4H, 5H, 6H, 7H, 8H, or about 9H or more. Hardness HB may be determined according to a number of established methods, for example, according to ASTM E10 or ISO 6506.

### Methods of Making

In one or more embodiments, a method of forming a quantum dot film 200 includes coating a quantum dot material on a first barrier layer 202 and disposing a second barrier layer on the quantum dot material 208 using a solution coating process. However, other process may be used. For example, the protective layer 204 may be formed by a method of coating a solution by means of roll coating, gravure coating, knife coating, dip coating, curtain flow coating, spray coating, bar coating, die coating, spin coating or inkjet coating, by using a dispenser, or other means.

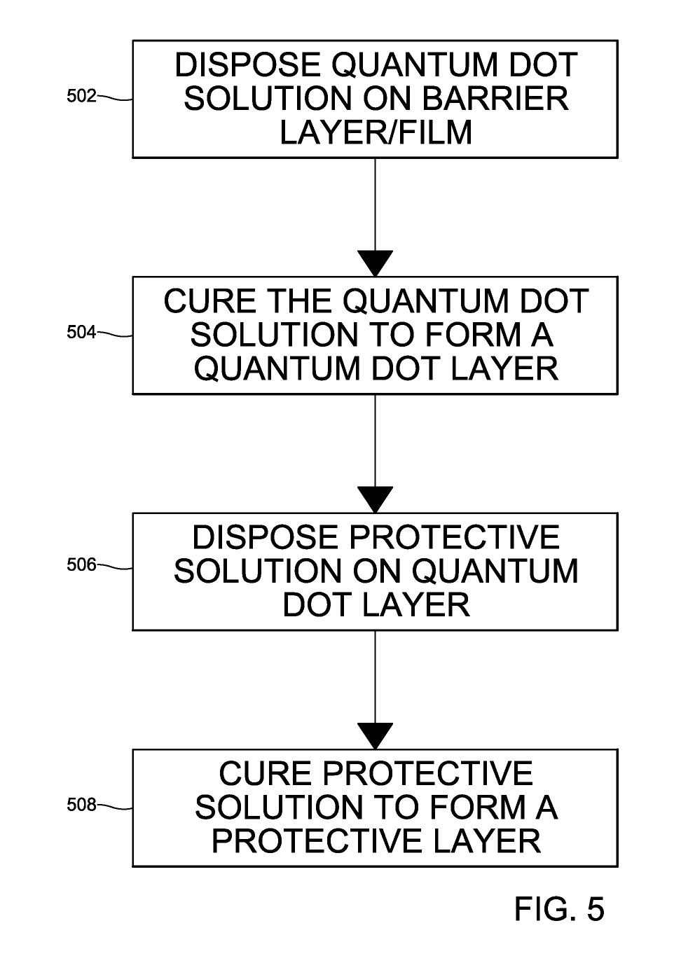

FIG. 5 shows a method according to aspects of the present disclosure. The method may comprises disposing a quantum dot solution on a barrier layer, at step 502. The quantum dot solution may be disposed on, at, or adjacent the barrier layer using a solution coating process.

At step 504, the quantum dot solution may be cured to form a quantum dot layer adhered to the barrier layer. The barrier layer may comprise a polysilazane-based polymer, a polysiloxane-based polymer, or a combination thereof.

At step 506, a protective solution may be disposed on the quantum dot layer. The protective solution may be disposed on the quantum dot layer using one or more of roll coating, gravure coating, knife coating, dip coating, curtain flow coating, spray coating, bar coating, die coating, spin coating or inkjet coating, by using a dispenser, or a combination thereof.

At step 508, the protective solution may be cured to form a protective layer adhered to the quantum dot layer. The protective solution may be cured using one or more of a radiation curing process and a thermal curing process. The protective layer inhibits the permeation of at least oxygen and moisture into the quantum dot layer. The protective layer may comprise or consists essentially of or consist of a functional layer disposed adjacent an inorganic layer. The inorganic layer of the protective layer may include a polysilazane-based polymer, a polysiloxane-based polymer, or a combination thereof. The protective layer may comprise, consists essentially of, or consist of a functional layer disposed adjacent a hybrid layer. The hybrid layer of the protective layer may comprises an organic component and an inorganic component. The inorganic component may comprise at least polysilazane-based polymer, a polysiloxane-based polymer, or a combination thereof.

Once cured, the protective layer may have a thickness that is less than the thickness of the barrier layer. As an example, the barrier layer may have a thickness of 50 microns and the protective layer may have a thickness of less than 50 microns. As another example, the barrier layer may have a thickness of 100 microns and the protective layer may have a thickness of less than 100 microns. Since the protective layer may have a thickness that is less than the barrier layer, the overall thickness of the stack of layers may be minimized compared to a stack having two of the barrier layers.

### Aspects

The present disclosure comprises at least the following aspects.

Aspect 1. An article comprising: a barrier layer comprising a substrate and an inorganic layer; a quantum dot layer disposed on the barrier layer; a protective layer disposed on the quantum dot layer, the protective layer comprising a functional layer disposed adjacent one or more of an inorganic layer and a hybrid layer, wherein the protective layer inhibits the permeation of at least oxygen and moisture into the quantum dot layer.

Aspect 2. An article consisting essentially of: a barrier layer comprising a substrate and an inorganic layer; a quantum dot layer disposed on the barrier layer; a protective layer disposed on the quantum dot layer, the protective layer comprising a functional layer disposed adjacent one or more of an inorganic layer and a hybrid layer, wherein the protective layer inhibits the permeation of at least oxygen and moisture into the quantum dot layer.

Aspect 3. An article consisting of: a barrier layer comprising a substrate and an inorganic layer; a quantum dot layer disposed on the barrier layer; a protective layer disposed on the quantum dot layer, the protective layer comprising a functional layer disposed adjacent one or more of an inorganic layer and a hybrid layer, wherein the protective layer inhibits the permeation of at least oxygen and moisture into the quantum dot layer.

Aspect 4. The film of any one of aspects 1-3, wherein the protective layer consists essentially of the functional layer disposed adjacent one or more of the inorganic layer and the hybrid layer.

Aspect 5. The film of any one aspects 1-4, wherein the inorganic layer of the barrier layer comprises a polysilazane-based polymer, a polysiloxane-based polymer, or a combination thereof.

Aspect 6. The film of any one aspects 1-5, wherein the quantum dot layer is disposed at or adjacent the barrier layer using a solution coating process.

Aspect 7. The film of any one aspects 1-6, wherein the functional layer of the protective layer comprises a diffuser.

Aspect 8. The film of any one aspects 17, wherein the protective layer comprises the inorganic layer and the inorganic layer comprises a polysilazane-based polymer, a polysiloxane-based polymer, or a combination thereof.

Aspect 9. The film of any one aspects 1-8, wherein the protective layer comprises the hybrid layer and the hybrid layer comprises an organic component and inorganic component. 10. The film of any one aspects 1-9, wherein the protective layer is disposed on the quantum dot layer using a solution coating process.

Aspect 11. A light emitting device comprising the film of any one of aspects 1-10.

Aspect 12. A film for light emitting devices, the film formed from a process comprising: disposing a quantum dot solution on a barrier layer; curing the quantum dot solution to form a quantum dot layer adhered to the barrier layer; disposing a protective solution on the quantum dot layer; and curing the protective solution to form a protective layer adhered to the quantum dot layer, wherein the film comprises a stack of the barrier layer, the quantum dot layer, and the protective layer, and wherein the protective layer inhibits the permeation of at least oxygen and moisture into the quantum dot layer.

Aspect 13. A film for light emitting devices, the film formed from a process consisting essentially of: disposing a quantum dot solution on a barrier layer; curing the quantum dot solution to form a quantum dot layer adhered to the barrier layer; disposing a protective solution on the quantum dot layer; and curing the protective solution to form a protective layer adhered to the quantum dot layer, wherein the film comprises a stack of the barrier layer, the quantum dot layer, and the protective layer, and wherein the protective layer inhibits the permeation of at least oxygen and moisture into the quantum dot layer.

Aspect 14. A film for light emitting devices, the film formed from a process consisting of: disposing a quantum dot solution on a barrier layer; curing the quantum dot solution to form a quantum dot layer adhered to the barrier layer; disposing a protective solution on the quantum dot layer; and curing the protective solution to form a protective layer adhered to the quantum dot layer, wherein the film comprises a stack of the barrier layer, the quantum dot layer, and the protective layer, and wherein the protective layer inhibits the permeation of at least oxygen and moisture into the quantum dot layer.

Aspect 15. The film of any one of aspects 12-14, wherein the protective layer consists essentially of a functional layer disposed adjacent an inorganic layer.

Aspect 16. The film of aspect 15, wherein the inorganic layer of the protective layer comprises a polysilazane-based polymer, a polysiloxane-based polymer, or a combination thereof.

Aspect 17. The film of any one of aspects 12-14, wherein the protective layer consists essentially of a functional layer disposed adjacent a hybrid layer.

Aspect 18. The film of aspect 17, wherein the hybrid layer of the protective layer comprises at least polysilazane-based polymer, a polysiloxane-based polymer, or a combination thereof.

Aspect 19. The film of any one aspects any one of aspects 12-18, wherein the barrier layer comprises a polysilazane-based polymer, a polysiloxane-based polymer, or a combination thereof.

Aspect 20. The film of any one aspects 12-20, wherein the quantum dot solution is disposed on the barrier layer using a solution coating process.

Aspect 21. The film of any one aspects 12 and 18-20, wherein the protective layer comprises a functional layer.

Aspect 22. The film of aspect 21, wherein the functional layer of the protective layer comprises a diffuser.

Aspect 23. The film of any one aspects 12-22, wherein the protective solution is disposed on the quantum dot layer using a solution coating process.

Aspect 24. The film of any one aspects 12-23, wherein the protective solution is cured using one or more of a radiation curing process and a thermal curing process.

Aspect 25. The film of any one aspects 12-23, wherein the protective solution is disposed on the quantum dot layer using one or more of roll coating, gravure coating, knife coating, dip coating, curtain flow coating, spray coating, bar coating, die coating, spin coating or inkjet coating, by using a dispenser, or a combination thereof.

Aspect 26. A light emitting device comprising the film of any one of aspects 12-25.

Aspect 27. A method of making a film, the method comprising: disposing a quantum dot solution on a barrier layer; curing the quantum dot solution to form a quantum dot layer adhered to the barrier layer; disposing a protective solution on the quantum dot layer; and curing the protective solution to form a protective layer adhered to the quantum dot layer, wherein the film comprises a stack of the barrier layer, the quantum dot layer, and the protective layer, and wherein the protective layer inhibits the permeation of at least oxygen and moisture into the quantum dot layer.

Aspect 28. A method of making a film, the method consisting essentially of: disposing a quantum dot solution on a barrier layer; curing the quantum dot solution to form a quantum dot layer adhered to the barrier layer; disposing a protective solution on the quantum dot layer; and curing the protective solution to form a protective layer adhered to the quantum dot layer, wherein the film comprises a stack of the barrier layer, the quantum dot layer, and the protective layer, and wherein the protective layer inhibits the permeation of at least oxygen and moisture into the quantum dot layer.

Aspect 29. A method of making a film, the method consisting of: disposing a quantum dot solution on a barrier layer; curing the quantum dot solution to form a quantum dot layer adhered to the barrier layer; disposing a protective solution on the quantum dot layer; and curing the protective solution to form a protective layer adhered to the quantum dot layer, wherein the film comprises a stack of the barrier layer, the quantum dot layer, and the protective layer, and wherein the protective layer inhibits the permeation of at least oxygen and moisture into the quantum dot layer.

Aspect 30. The method of any one of aspects 27-29, wherein the protective layer consists essentially of a functional layer disposed adjacent an inorganic layer.

Aspect 31. The method of aspect 30, wherein the inorganic layer of the protective layer comprises a polysilazane-based polymer, a polysiloxane-based polymer, or a combination thereof.

Aspect 32. The method of any one of aspects 27-29, wherein the protective layer consists essentially of a functional layer disposed adjacent a hybrid layer.

Aspect 33. The method of aspect 32, wherein the hybrid layer of the protective layer comprises at least polysilazane-based polymer, a polysiloxane-based polymer, or a combination thereof.

Aspect 34. The method of any one aspects 27-33, wherein the barrier layer comprises a polysilazane-based polymer, a polysiloxane-based polymer, or a combination thereof.

Aspect 35. The method of any one aspects 27-34, wherein the quantum dot solution is disposed on the barrier layer using a solution coating process.

Aspect 36. The method of any one aspects 23 and 27-29, wherein the protective layer comprises a functional layer.

Aspect 37. The method of aspect 36, wherein the functional layer of the protective layer comprises a diffuser.

Aspect 38. The method of any one aspects 27-37, wherein the protective solution is disposed on the quantum dot layer using a solution coating process.

Aspect 39. The method of any one aspects 27-28, wherein the protective solution is cured using one or more of a radiation curing process and a thermal curing process.

Aspect 39. The method of any one aspects 27-39, wherein the protective solution is disposed on the quantum dot layer using one or more of roll coating, gravure coating, knife coating, dip coating, curtain flow coating, spray coating, bar coating, die coating, spin coating or inkjet coating, by using a dispenser, or a combination thereof.

### Definitions

It is to be understood that the terminology used herein is for the purpose of describing particular aspects only and is not intended to be limiting. As used in the specification and in the claims, the term “comprising” may include the embodiments “consisting of” and “consisting essentially of.” Unless defined otherwise, all technical and scientific terms used herein have the same meaning as commonly understood by one of ordinary skill in the art to which this disclosure belongs. In this specification and in the claims which follow, reference will be made to a number of terms which shall be defined herein.

Throughout this document, values expressed in a range format should be interpreted in a flexible manner to include not only the numerical values explicitly recited as the limits of the range, but also to include all the individual numerical values or sub-ranges encompassed within that range as if each numerical value and sub-range is explicitly recited. For example, a range of “about 0.1% to about 5%” or “about 0.1% to 5%” should be interpreted to include not just about 0.1% to about 5%, but also the individual values (e.g., 1%, 2%, 3%, and 4%) and the sub-ranges (e.g., 0.1% to 0.5%, 1.1% to 2.2%, 3.3% to 4.4%) within the indicated range. The statement “about X to Y” has the same meaning as “about X to about Y,” unless indicated otherwise. Likewise, the statement “about X, Y, or about Z” has the same meaning as “about X, about Y, or about Z,” unless indicated otherwise. The term “about” as used herein may allow for a degree of variability in a value or range, for example, within 10%, within 5%, or within 1% of a stated value or of a stated limit of a range, and includes the exact stated value or range. The term “substantially” as used herein refers to a majority of, or mostly, as in at least about 50%, 60%, 70%, 80%, 90%, 95%, 96%, 97%, 98%, 99%, 99.5%, 99.9%, 99.99%, or at least about 99.999% or more, or 100%.

Ranges may be expressed herein as from one value (first value) to another value (second value). When such a range is expressed, the range includes in some aspects one or both of the first value and the second value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. It is also understood that each unit between two particular units are also disclosed. For example, if 10 and 15 are disclosed, then 11, 12, 13, and 14 are also disclosed.

In this document, the terms “a,” “an,” or “the” are used to include one or more than one unless the context clearly dictates otherwise. The term “or” is used to refer to a nonexclusive “or” unless otherwise indicated. The statement “at least one of A and B” has the same meaning as “A, B, or A and B.” In addition, it is to be understood that the phraseology or terminology employed herein, and not otherwise defined, is for the purpose of description only and not of limitation. Any use of section headings is intended to aid reading of the document and is not to be interpreted as limiting; information that is relevant to a section heading may occur within or outside of that particular section.

In the methods described herein, the acts may be carried out in any order without departing from the principles of the invention, except when a temporal or operational sequence is explicitly recited. Furthermore, specified acts may be carried out concurrently unless explicit claim language recites that they be carried out separately. For example, a claimed act of doing X and a claimed act of doing Y may be conducted simultaneously within a single operation, and the resulting process will fall within the literal scope of the claimed process.

The term “organic group” as used herein refers to any carbon-containing functional group. For example, an oxygen-containing group such as an alkoxy group, aryloxy group, aralkyloxy group, oxo(carbonyl) group, a carboxyl group including a carboxylic acid, carboxylate, and a carboxylate ester; a sulfur-containing group such as an alkyl and aryl sulfide group; and other heteroatom-containing groups. Non-limiting examples of organic groups include OR, OOR, OC(O)N(R)₂, CN, CF₃, OCF₃, R, C(O), methylenedioxy, ethylenedioxy, N(R)₂, SR, SOR, SO₂R, SO₂N(R)₂, SO₃R, C(O)R, C(O)C(O)R, C(O)CH₂C(O)R, C(S)R, C(O)OR, OC(O)R, C(O)N(R)₂, OC(O)N(R)₂, C(S)N(R)₂, (CH₂)₀₋₂N(R)C(O)R, (CH₂)₀₋₂N(R)N(R)₂, N(R)N(R)C(O)R, N(R)N(R)C(O)OR, N(R)N(R)CON(R)₂, N(R)SO₂R, N(R)SO₂N(R)₂, N(R)C(O)OR, N(R)C(O)R, N(R)C(S)R, N(R)C(O)N(R)₂, N(R)C(S)N(R)₂, N(COR)COR, N(OR)R, C(═NH)N(R)₂, C(O)N(OR)R, C(═NOR)R, and substituted or unsubstituted (C₁-C₁₀₀)hydrocarbyl, wherein R may be hydrogen (in examples that include other carbon atoms) or a carbon-based moiety, and wherein the carbon-based moiety may be substituted or unsubstituted.

The term “substituted” as used herein in conjunction with a molecule or an organic group as defined herein refers to the state in which one or more hydrogen atoms contained therein are replaced by one or more non-hydrogen atoms. The term “functional group” or “substituent” as used herein refers to a group that may be or is substituted onto a molecule or onto an organic group. Examples of substituents or functional groups include, but are not limited to, a halogen (e.g., F, Cl, Br, and I); an oxygen atom in groups such as hydroxy groups, alkoxy groups, aryloxy groups, aralkyloxy groups, oxo(carbonyl) groups, carboxyl groups including carboxylic acids, carboxylates, and carboxylate esters; a sulfur atom in groups such as thiol groups, alkyl and aryl sulfide groups, sulfoxide groups, sulfone groups, sulfonyl groups, and sulfonamide groups; a nitrogen atom in groups such as amines, hydroxyamines, nitriles, nitro groups, N-oxides, hydrazides, azides, and enamines; and other heteroatoms in various other groups. Non-limiting examples of substituents that may be bonded to a substituted carbon (or other) atom include F, Cl, Br, I, OR, OC(O)N(R)₂, CN, NO, NO₂, ONO₂, azido, CF₃, OCF₃, R, O (oxo), S (thiono), C(O), S(O), methylenedioxy, ethylenedioxy, N(R)₂, SR, SOR, SO₂R, SO₂N(R)₂, SO₃R, C(O)R, C(O)C(O)R, C(O)CH₂C(O)R, C(S)R, C(O)OR, OC(O)R, C(O)N(R)₂, OC(O)N(R)₂, C(S)N(R)₂, (CH₂)₀₋₂N(R)C(O)R, (CH₂)₀₋₂N(R)N(R)₂, N(R)N(R)C(O)R, N(R)N(R)C(O)OR, N(R)N(R)CON(R)₂, N(R)SO₂R, N(R)SO₂N(R)₂, N(R)C(O)OR, N(R)C(O)R, N(R)C(S)R, N(R)C(O)N(R)₂, N(R)C(S)N(R)₂, N(COR)COR, N(OR)R, C(═NH)N(R)₂, C(O)N(OR)R, and C(═NOR)R, wherein R may be hydrogen or a carbon-based moiety; for example, R may be hydrogen, (C₁-C₁₀₀)hydrocarbyl, alkyl, acyl, cycloalkyl, aryl, aralkyl, heterocyclyl, heteroaryl, or heteroarylalkyl; or wherein two R groups bonded to a nitrogen atom or to adjacent nitrogen atoms may together with the nitrogen atom or atoms form a heterocyclyl.

The term “alkyl” as used herein refers to straight chain and branched alkyl groups and cycloalkyl groups. Examples of straight chain alkyl groups include those with from 1 to 8 carbon atoms such as methyl, ethyl, n-propyl, n-butyl, n-pentyl, n-hexyl, n-heptyl, and n-octyl groups. Examples of branched alkyl groups include, but are not limited to, isopropyl, iso-butyl, sec-butyl, t-butyl, neopentyl, isopentyl, and 2,2-dimethylpropyl groups.

The term “alkenyl” as used herein refers to straight and branched chain and cyclic alkyl groups as defined herein, except that at least one double bond exists between two carbon atoms.

The term “acyl” as used herein refers to a group containing a carbonyl moiety wherein the group is bonded via the carbonyl carbon atom.

The term “cycloalkyl” as used herein refers to cyclic alkyl groups such as, but not limited to, cyclopropyl, cyclobutyl, cyclopentyl, cyclohexyl, cycloheptyl, and cyclooctyl groups. In some embodiments, the cycloalkyl group may have 3 to about 8-12 ring members, whereas in other embodiments the number of ring carbon atoms range from 3 to 4, 5, 6, or 7

The term “aryl” as used herein refers to cyclic aromatic hydrocarbon groups that do not contain heteroatoms in the ring. Thus aryl groups include, but are not limited to, phenyl, azulenyl, heptalenyl, biphenyl, indacenyl, fluorenyl, phenanthrenyl, triphenylenyl, pyrenyl, naphthacenyl, chrysenyl, biphenylenyl, anthracenyl, and naphthyl groups.

The term “heterocyclyl” as used herein refers to aromatic and non-aromatic ring compounds containing three or more ring members, of which one or more is a heteroatom such as, but not limited to, N, O, and S.

The term “alkoxy” as used herein refers to an oxygen atom connected to an alkyl group, including a cycloalkyl group, as are defined herein.

The terms “halo,” “halogen,” or “halide” group, as used herein, by themselves or as part of another substituent, mean, unless otherwise stated, a fluorine, chlorine, bromine, or iodine atom.

The term “haloalkyl” group, as used herein, includes mono-halo alkyl groups, poly-halo alkyl groups wherein all halo atoms may be the same or different, and per-halo alkyl groups, wherein all hydrogen atoms are replaced by halogen atoms, such as fluoro. Examples of haloalkyl include trifluoromethyl, 1,1-dichloroethyl, 1,2-dichloroethyl, 1,3-dibromo-3,3-difluoropropyl, perfluorobutyl, and the like.

The term “hydrocarbon” or “hydrocarbyl” as used herein refers to a molecule or functional group, respectively, that includes carbon and hydrogen atoms. The term may also refer to a molecule or functional group that normally includes both carbon and hydrogen atoms but wherein all the hydrogen atoms are substituted with other functional groups.

As used herein, the term “hydrocarbyl” refers to a functional group derived from a straight chain, branched, or cyclic hydrocarbon, and may be alkyl, alkenyl, alkynyl, aryl, cycloalkyl, acyl, or any combination thereof. Hydrocarbyl groups may be shown as (Cₐ-C_{b})hydrocarbyl, wherein a and b are integers and mean having any of a to b number of carbon atoms. For example, (C₁-C₄)hydrocarbyl means the hydrocarbyl group may be methyl (C₁), ethyl (C₂), propyl (C₃), or butyl (C₄), and (C₀-C_{b})hydrocarbyl means in certain embodiments there is no hydrocarbyl group.

The term “number-average molecular weight” (Mₙ) as used herein refers to the ordinary arithmetic mean of the molecular weight of individual molecules in a sample. It is defined as the total weight of all molecules in a sample divided by the total number of molecules in the sample. Experimentally, Mₙ is determined by analyzing a sample divided into molecular weight fractions of species i having nᵢ molecules of molecular weight Mᵢ through the formula Mₙ=ΣMᵢnᵢ/Σnᵢ. The Mₙ may be measured by a variety of well-known methods including gel permeation chromatography, spectroscopic end group analysis, and osmometry. If unspecified, molecular weights of polymers given herein are number-average molecular weights.

The term “weight-average molecular weight” as used herein refers to M_{w}, which is equal to ΣMᵢ²nᵢ/ΣMᵢnᵢ, where nᵢ is the number of molecules of molecular weight Mᵢ. In various examples, the weight-average molecular weight may be determined using light scattering, small angle neutron scattering, X-ray scattering, and sedimentation velocity.

The term “radiation” as used herein refers to energetic particles travelling through a medium or space. Examples of radiation are visible light, infrared light, microwaves, radio waves, very low frequency waves, extremely low frequency waves, thermal radiation (heat), and black-body radiation.

The term “UV light” as used herein refers to ultraviolet light, which is electromagnetic radiation with a wavelength of about 10 nm to about 400 nm, or 10 nm to 400 nm.

The term “cure” as used herein refers to exposing to radiation in any form, heating, or allowing to undergo a physical or chemical reaction that results in hardening or an increase in viscosity.

The term “solvent” as used herein refers to a liquid that may dissolve a solid, liquid, or gas. Non-limiting examples of solvents are silicones, organic compounds, water, alcohols, ionic liquids, and supercritical fluids.

The term “coating” as used herein refers to a continuous or discontinuous layer of material on the coated surface, wherein the layer of material may penetrate the surface and may fill areas such as pores, wherein the layer of material may have any three-dimensional shape, including a flat or curved plane. In one example, a coating may be formed on one or more surfaces, any of which may be porous or nonporous, by immersion in a bath of coating material.

The term “surface” as used herein refers to a boundary or side of an object, wherein the boundary or side may have any perimeter shape and may have any three-dimensional shape, including flat, curved, or angular, wherein the boundary or side may be continuous or discontinuous. While the term surface generally refers to the outermost boundary of an object with no implied depth, when the term ‘pores’ is used in reference to a surface, it refers to both the surface opening and the depth to which the pores extend beneath the surface into the substrate.

As used herein, the term “polymer” refers to a molecule having at least one repeating unit and may include copolymers.

The polymers described herein may terminate in any suitable way. In some embodiments, the polymers may terminate with an end group that is independently chosen from a suitable polymerization initiator, —H, —OH, a substituted or unsubstituted (C₁-C₂₀)hydrocarbyl (e.g., (C₁-C₁₀)alkyl or (C₆-C₂₀)aryl) interrupted with 0, 1, 2, or 3 groups independently selected from —O—, substituted or unsubstituted —NH—, and —S—, a poly(substituted or unsubstituted (C₁-C₂₀)hydrocarbyloxy), and a poly(substituted or unsubstituted (C₁-C₂₀)hydrocarbylamino).

Illustrative types of polyethylene include, for example, ultra-high molecular weight polyethylene (UHMWPE), ultra-low molecular weight polyethylene (ULMWPE), high molecular weight polyethylene (HMWPE), high density polyethylene (HDPE), high density cross-linked polyethylene (HDXLPE), cross-linked polyethylene (PEX or XLPE), medium density polyethylene (MDPE), low density polyethylene (LDPE), linear low density polyethylene (LLDPE) and very low density polyethylene (VLDPE).

1. A multilayer film comprising:
a barrier layer comprising a substrate and an inorganic layer;
a quantum dot layer disposed on the barrier layer; and
a protective layer disposed on the quantum dot layer, the protective layer comprising a functional layer disposed adjacent one or more of an inorganic layer and a hybrid layer, wherein the hybrid layer comprises an organic component and an inorganic component, wherein the protective layer inhibits permeation of at least oxygen and moisture into the quantum dot layer and wherein the one or more of the inorganic layer and the hybrid layer comprises a polysilazane-based polymer, a polysiloxane-based polymer, or a combination thereof.

2. The film of claim 1, wherein the protective layer consists essentially of the functional layer disposed adjacent one or more of the inorganic layer and the hybrid layer.

3. The film of claim 1, wherein the quantum dot layer is disposed at or adjacent the barrier layer using a solution coating process.

4. The film of claim 1, wherein the functional layer of the protective layer comprises a diffuser.

5. The film of claim 1, wherein the protective layer comprises the inorganic layer and the inorganic layer comprises a polysilazane-based polymer, a polysiloxane-based polymer, or a combination thereof.

6. The film of claim 1, wherein the protective layer comprises the hybrid layer and the hybrid layer comprises an organic component and inorganic component.

7. The film of claim 1, wherein the protective layer is disposed on the quantum dot layer using a solution coating process.

8. A light emitting device comprising the film of claim 1.

9. A method of forming a film for light emitting devices, the method comprising:
disposing a quantum dot solution on a barrier layer;
curing the quantum dot solution to form a quantum dot layer adhered to the barrier layer;
disposing a protective solution on the quantum dot layer; and
curing the protective solution to form a protective layer adhered to the quantum dot layer, wherein the film comprises a stack of the barrier layer, the quantum dot layer, and the protective layer, and wherein the protective layer inhibits permeation of at least oxygen and moisture into the quantum dot layer, and wherein the inorganic layer comprises a polysilazane-based polymer, a polysiloxane-based polymer, or a combination thereof.

10. The method of claim 9, wherein the protective layer consists essentially of a functional layer disposed adjacent a hybrid layer.

11. The method of claim 10, wherein the hybrid layer of the protective layer comprises at least polysilazane-based polymer, a polysiloxane-based polymer, or a combination thereof.

12. The method of claim 9, wherein the barrier layer comprises a polysilazane-based polymer, a polysiloxane-based polymer, or a combination thereof.

13. The method of claim 9, wherein the quantum dot solution is disposed on the barrier layer using a solution coating process.

14. The method of claim 9, wherein the protective layer comprises a functional layer.

15. The method of claim 9, wherein the protective solution is cured using one or more of a radiation curing process and a thermal curing process.

16. The method of claim 9, wherein the protective solution is disposed on the quantum dot layer using one or more of roll coating, gravure coating, knife coating, dip coating, curtain flow coating, spray coating, bar coating, die coating, spin coating or inkjet coating, by using a dispenser, or a combination thereof.

17. A light emitting device comprising a film formed according to the method of claim 9.
